(19) United States
(12) Patent Application Publication
(10) Pub. No.: US 2008/0048687 A1
(43) Pub. Date: Feb. 28, 2008

(54) PROBE, METHOD OF MANUFACTURING THE PROBE AND PROBE CARD HAVING THE PROBE

(76) Inventor: Moon-Hyuck Jung, Seoul (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 11/830,405

(22) Filed: Jul. 30, 2007

(30) Foreign Application Priority Data
Jul. 31, 2006 (KR) 10-2006-0072025

(51) Int. Cl. G01R 31/26; B44C 1/22; C23F 1/00

(52) U.S. Cl. 324/754; 216/38; 216/41

(57) ABSTRACT

A probe, a method of manufacturing the probe and a probe card having the probe are disclosed. The probe includes a first connecting member, a body and a tip. Specially, the body integrally includes a bump and a beam. The body is fixed to an electric component by the first connecting member. In addition, the probe card may include a printed circuit board and the electric component as well as the above probe. Here, the probe is independently formed. The probe is then fixed to the electric component so that damage to the electric component may be effectively prevented.

### CROSS REFERENCE TO RELATED APPLICATION

This application claims benefit of priority under 35 U.S.C. § 119 from Korean Patent Application No. 2006-72025 filed on Jul. 31, 2006, in the Korean Intellectual Property Office, the disclosure of which is incorporated herein by reference in its entirety.

### BACKGROUND OF THE INVENTION

1. Field of the Invention

The present invention relates to a probe, a method of manufacturing the probe and a probe card having the probe. More particularly, the present invention relates to a probe card used to examine a semiconductor chip, a probe included in the probe card and a method of manufacturing the probe card.

2. Description of the Related Art

A probe card is used to examine a semiconductor chip after the semiconductor chip is manufactured.

FIG. 1 is a cross-sectional view illustrating a conventional probe included in a conventional probe card.

Particularly, the probe in FIG. 1 is disclosed in Korean Patent Laid-open publication No. 1997-704546. Referring to FIG. 1, an electric component designated as an electric element 734 has a corresponding terminal 732. A bump designated as a mutual connection element 730 is connected to the corresponding terminal 732. The mutual connection element 730 is connected to the filling structure 736 by a cantilever structure 720 integrally including a tip and a beam. The filling structure 736 may be formed by a soldering process or a blazing process.

However, the conventional probe has structural disadvantages. In addition, many problems occur in processes for manufacturing the conventional probe.

The cantilever structure 720 may be connected to the mutual connection element 730 by using the filling structure 736 such as a solder ball or a blazing. In this case a connection portion is relatively weak. Thus, the connection portion may be broken when the tip integrally included in the cantilever structure 720 is connected to a pad of a semiconductor chip to examine the semiconductor chip.

In addition, the interval between the mutual connection elements 730 is relatively small so that an electric short may be generated when the cantilever structure 720 is connected to the mutual connection element 730 by using the filling structure 736 such as the solder ball and the blazing.

Further, a photolithography process is directly performed on the electric component 8 to form the mutual connection element 730 so that the electric component 8 may be damaged.

### SUMMARY OF THE INVENTION

The present invention provides a probe capable of reducing damage to an electric component.

The present invention provides a method of manufacturing the probe.

The present invention provides a probe card including the probe.

In accordance with an embodiment of the present invention, a probe includes a first connecting member, a body and a tip. The first connecting member is formed on an electric component to be electrically connected to the electric component. The body integrally includes a bump fixed to the electric component by the first connecting member and a beam connected to the bump such that the beam is spaced apart from the electric component. The tip is formed on the beam. The tip makes contact with a pad of a semiconductor chip to examine the semiconductor chip.

The probe may further include the second connecting member located between the beam and the tip to electrically connect the beam to the tip. The tip may have a stepped shape having a width becoming smaller in a direction from a portion of the tip connected to the beam toward a portion of the tip making contact with the pad of the semiconductor chip. The bump and beam may be formed as one body having a substantially reversed “L” shape.

In accordance with an embodiment of the present invention, a body structure inside which a body integrally including a bump extending in a vertical direction and a beam extending in a horizontal direction such that the beam is connected to the bump is formed. The bump is exposed from a lower surface of the body structure. The beam is exposed from an upper surface of the body structure. A tip structure inside which a tip is formed is formed. The tip is exposed from a lower surface of the tip structure. A first connecting member is formed between an electric component and the bump to connect the body structure to the electric component. A portion of the body structure except the body and a portion of the tip structure except for the tip are removed.

A second connecting member may be further formed between the beam and the tip to fix the tip structure to the body structure. The first connecting member may be formed after the second connecting member is formed. As one alternative, the first connecting member may be formed before the second connecting member is formed. As another alternative, the first connecting member may be formed simultaneously with the second connecting member.

In accordance with an embodiment of the present invention, a probe card includes a printed circuit board, an electric component and a probe. The electric component is electrically connected to the printed circuit board. The probe includes a first connecting member, a body and a tip. The first connecting member is formed on the electric component to be connected to the electric component. The body integrally includes a bump and a beam. The bump is fixed to the electric component by the first connecting member. The beam is connected to the bump such that the beam is spaced apart from the electric component. The tip is formed on the beam. The tip makes contact with a pad of a semiconductor chip to examine the semiconductor chip.

According to an embodiment of the present invention, a bump and a beam are integrally formed. Thus, the yield and durability of the probe may be larger than that formed by a conventional process in which the bump and the beam are independently formed.

In addition, a photolithography process may not be performed directly on an electric component that is relatively expensive when the bump is formed. Thus, damage to the electric component may be reduced.

### BRIEF DESCRIPTION OF THE DRAWINGS

The above and other advantages of the present invention will become readily apparent by reference to the following detailed description when considered in conjunction with the accompanying drawings in which:

FIG. 1 is a cross-sectional view illustrating a conventional probe card;

FIG. 2 is a cross-sectional view illustrating a probe 100 in accordance with an embodiment of the present invention;

FIGS. 3 to 8 are cross-sectional views illustrating a body structure in accordance with an embodiment of the present invention;

FIGS. 9 to 16 are cross-sectional views illustrating a method of forming the body structure;

FIGS. 17 to 23 are cross-sectional views illustrating a method of forming the body structure in accordance with an embodiment of the present invention;

FIGS. 24 to 30 are cross-sectional views illustrating a method of forming a body structure in accordance with an embodiment of the present invention;

FIGS. 31 to 36 are cross-sectional views illustrating a method of forming a body structure;

FIGS. 37 to 40 are cross-sectional views illustrating a method of forming a body structure in accordance with an embodiment of the present invention;

FIGS. 41 to 47 are cross-sectional views illustrating a method of forming a tip structure in accordance with an embodiment of the present invention;

FIGS. 51 to 56 are cross-sectional views illustrating a method of manufacturing the probe 200;

FIG. 56 is an enlarged cross-sectional view of a portion “A” in FIG. 55;

FIG. 57 is a cross-sectional view illustrating a probe card in accordance with an embodiment of the present invention; and

FIG. 58 is an enlarged cross-sectional view of a portion “B” in FIG. 57.

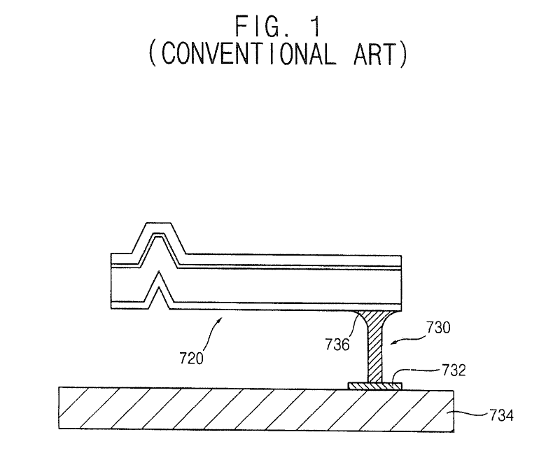

### DESCRIPTION OF THE EMBODIMENTS

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, no intervening elements or layers are present.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of the present invention.

Spatially relative terms, such as “beneath,” “below,” “lower,” “above,” “upper” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and “including” specify the presence of stated features, integers, steps, operations, elements, and/or components, but do not preclude the presence and/or addition of one or more other features, integers, steps, operations, elements, components, and/or groups thereof.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include a fourth member, whereas the expression “at least one selected from the group consisting of A, B, and C” does not.

As used herein, the expression “or” is not an “exclusive or” unless it is used in conjunction with the phrase “either.” For example, the expression “A, B, or C” includes A alone; B alone; C alone; both A and B together; both A and C together; both B and C together; and all three of A, B and, C together, whereas the expression “either A, B, or C” means one of A alone, B alone, and C alone, and does not mean any of both A and B together; both A and C together; both B and C together; and all three of A, B and C together.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention. Like reference numerals refer to like elements throughout.

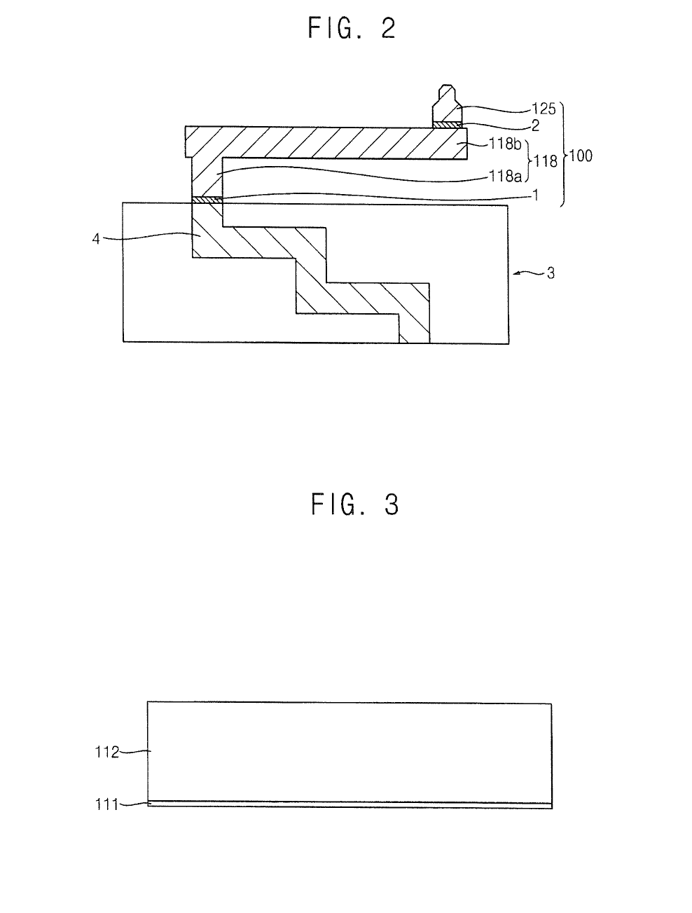

FIG. 2 is a cross-sectional view illustrating a probe 100 in accordance with an embodiment of the present invention.

Referring to FIG. 2, the probe 100 may include a first connecting member 1, a body 118, a second connecting member 2 and a tip 125.

The body 118 may be integrally formed with the bump 118a extending in a vertical direction and the beam 118b extending in a horizontal direction. The body may include a conductive material such as a metal or an alloy. The conductive material may be nickel (Ni), nickel-cobalt (Ni—Co) or nickel-tungsten-cobalt (Ni—W—Co).

The bump 118a and the beam 118b may be integrally formed with each other. For example, the bump 118a and the beam 118b may be formed by the same deposition process. In this case, a physical interface may not be generated between the bump 118a and the beam 118b. The body 118 may have a shape folded at a substantially right angle. That is, the bump 118a and the beam 118b may be formed as one body having a substantially reversed “L” shape.

The first connecting member 1 is formed between a wire 4 of an electric component 3 and the bump 118a of the body 118 so that the body 118 may be fixed to the electric component 3. Here, the electric component 3 may be a ceramic board, a space transformer, etc. The first connecting member 1 may include a conductive material such as a lead (Pb). The first connecting portion 1 may be formed by a screen printing process. The second connecting member 2 is formed between the beam 118b of the body 118 and the tip 125 so that the tip 125 may be fixed to the beam 118b. The second connecting member 2 may include a conductive material such as a lead. The second connecting member 2 may be formed by a screen printing process.

The tip 125 extends on the second connecting member 2 in a vertical direction. The tip 125 may include a conductive material such as a metal or an alloy. The conductive material may be nickel, nickel-cobalt or nickel-tungsten-cobalt. The tip 125 may make contact with a pad of a semiconductor chip to inspect the semiconductor chip. Thus, a width of the tip 125 may decrease in a direction from a portion of the tip 125 connected to the beam 118b toward a portion of the tip 125 making contact with the pad of the semiconductor chip. That is, an upper portion of the tip 125 may have a width lower than a lower portion of the tip 125. For example, a width of the tip 125 may continuously decrease in a direction from the lower portion of the tip 125 toward the upper portion of the tip 125. Alternatively, the width of the tip 125 may discontinuously decrease in the direction from the lower portion of the tip 125 toward the upper portion of the tip 125.

The body 118 integrally including the bump 118a and the beam 118b may provide elasticity when the tip 125 makes contact with the pad of the semiconductor chip. Thus, the beam 118b may be spaced apart from the electric component by the bump 118a.

Hereinafter, a method of manufacturing the probe 100 in FIG. 2 is described. Here, structures required for manufacturing the probe may be indicated using different reference numerals for convenience of explanation.

FIGS. 3 to 49 are cross-sectional views illustrating a method of manufacturing the probe 100 in FIG. 2.

In addition, processes for forming a body structure required for forming a body of the probe 100 in FIG. 2, a tip structure required for forming the tip and the first connecting member are also described.

FIGS. 3 to 8 are cross-sectional views illustrating a method of forming a body structure in accordance with an embodiment of the present invention.

Referring to FIG. 3, a lower surface of a sacrificial layer 112 is oxidized to from an etch stop layer 111. In this case, the sacrificial layer 112 and the etch stop layer 111 may include silicon and silicon oxide, respectively. Although not particularly illustrated in the drawings, an upper surface of the sacrificial layer 112 may be oxidized to form a protection layer. For example, the sacrificial layer 112 may be a silicon substrate.

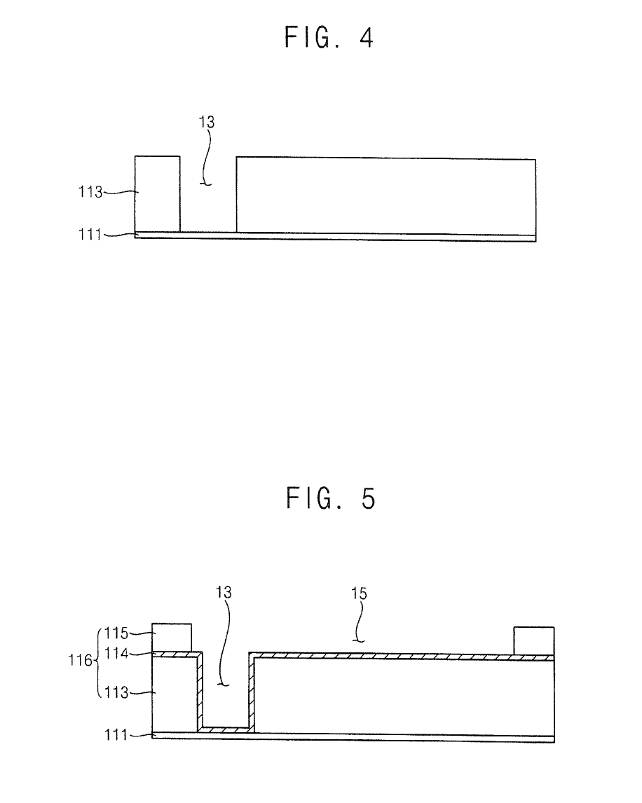

Referring to FIG. 4, the sacrificial layer 112 is partially etched until the etch stop layer 111 is exposed so that a sacrificial layer pattern 113 having a first hole 13 exposing the etch stop layer 111 may be formed.

Referring to FIG. 5, a seed layer 114 having a relatively uniform thickness is formed on the sacrificial layer pattern 113 and the etch stop layer 111 such that the seed layer 114 may be conformed to an inner face of the first hole 13. Thereafter, a photoresist layer pattern 115 is formed on the seed layer 114. The photoresist layer pattern 115 may have a second hole 15. Here, the second hole 15 is communicated with the first hole 13 having the inner face on which the seed layer 114 is formed. In addition, the second hole 15 may have a width substantially larger than that of the first hole 13.

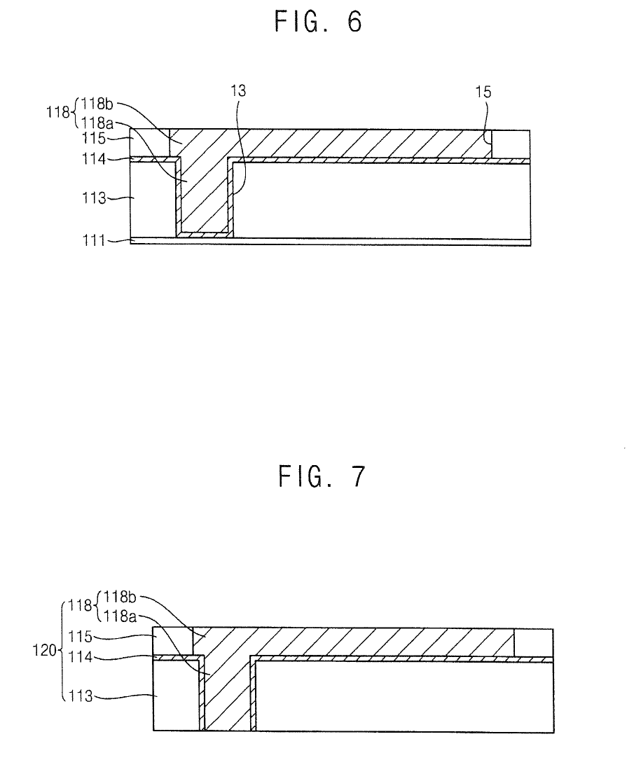

Referring to FIG. 6, a conductive material is deposited on the seed layer 114 so that the body 118 integrally including the bump 118a and the beam 118b may be formed. The body 118 may be formed using a conductive material such as a metal or an alloy. The conductive material may be nickel, nickel-cobalt or nickel-tungsten-cobalt.

The body 118 may be formed by a deposition process such as an electroplating process, a physical vapor deposition (PVD) process, a chemical vapor deposition (CVD) process.

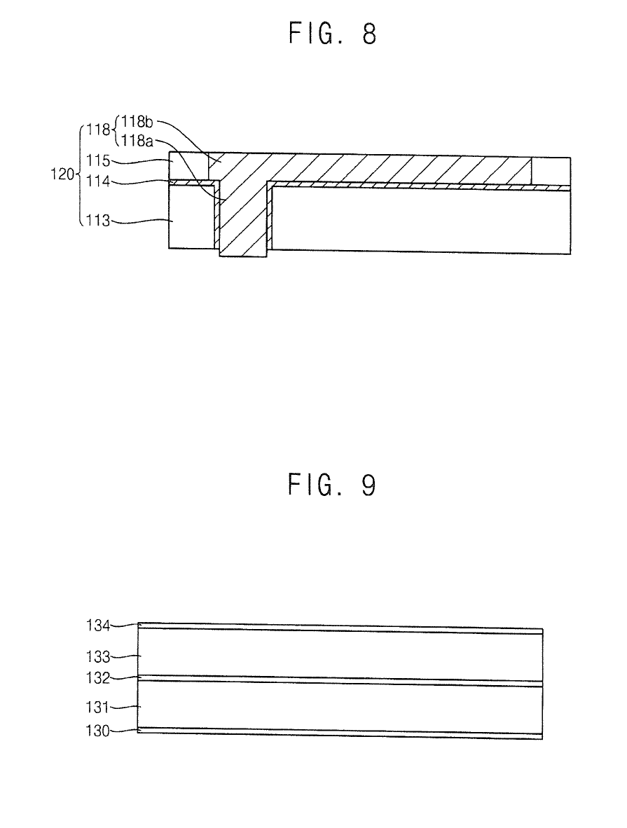

Referring to FIG. 7, a planarization process is performed on the etch stop layer 111, the seed layer 114 and the sacrificial layer pattern 113. The etch stop layer 111 may be completely removed by the planarization process. In addition, the seed layer 114 and the sacrificial layer pattern 113 are partially removed. Thus, the bump 118a may be exposed.

As a result, a body structure 120 may be formed. The body 118 integrally including the bump 118a extending in the vertical direction and the beam 118b extending in the horizontal direction may be included inside the body structure 120. The bump 118a may be exposed from a lower surface of the body structure 120. The beam 118b may be exposed from an upper surface of the body structure 120.

Referring to FIG. 8, an etching process is performed on the lower surface of the body structure 120 so that the sacrificial layer pattern 113 and the seed layer 114 are partially removed. The bump 118a may be partially protruded by the etching process. Here, the etching process is an optional process so that the etching process may not be performed.

The body structure may be formed by the above method. However, the body structure may be formed by various methods. Hereinafter, other methods of forming the body structure are explained.

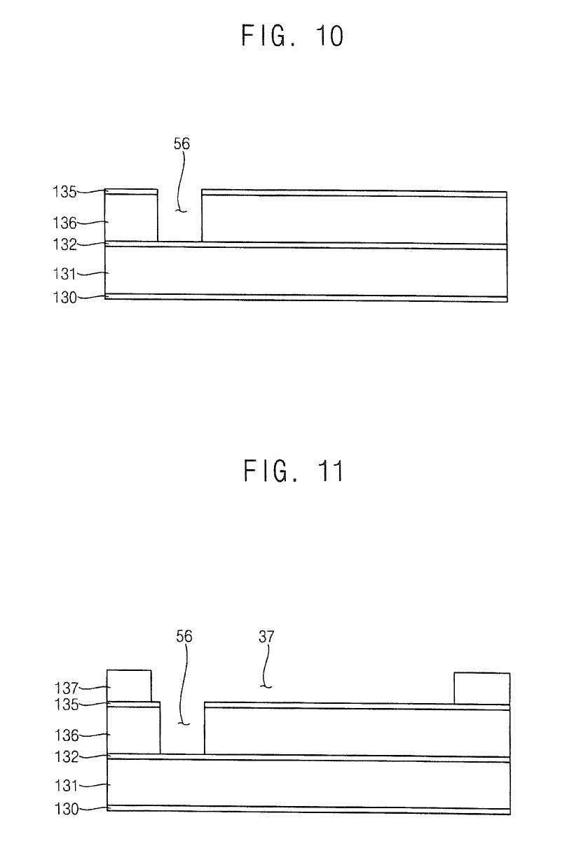

FIGS. 9 to 16 are cross-sectional views illustrating a method of forming the body structure in accordance with another example embodiment.

Referring to FIG. 9, a first etch stop layer 130, a first sacrificial layer 131, a second etch stop layer 132, a second sacrificial layer 133 and a third etch stop layer 134 are successively formed.

Referring to FIG. 10, the third etch stop layer 134 and the second sacrificial layer 133 are etched to form a preliminary third etch stop layer pattern 135 and a preliminary second sacrificial layer pattern 136. The preliminary third etch stop layer pattern 135 and the preliminary second sacrificial layer pattern 136 together may have a first hole 56 exposing the second etch stop layer 132.

Referring to FIG. 11, a mask layer pattern 137 is formed on the preliminary third etch stop layer pattern 135. The mask layer pattern 137 has a second hole 37 communicated with the first hole 56. The second hole 37 may extend in a horizontal direction.

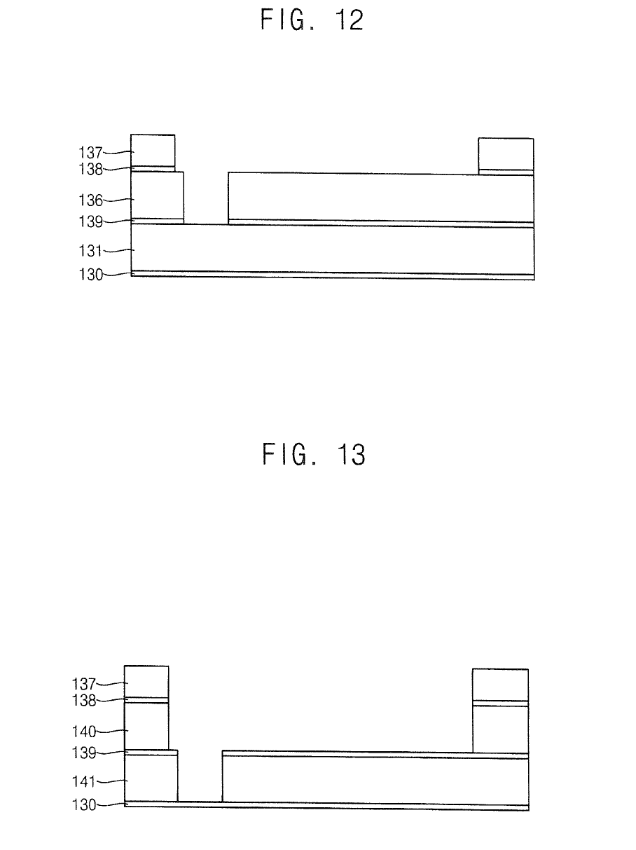

Referring to FIG. 12, a portion of the preliminary third etch stop layer pattern 135 that is not covered with the mask layer pattern 137 and a portion of the second etch stop layer 132 that is not covered with the preliminary second sacrificial layer pattern 136 are etched so that a third etch stop layer pattern 138 and a second etch stop layer pattern 139 may be formed.

Referring to FIG. 13, a portion of the preliminary second sacrificial layer pattern 136 that is not covered with the third etch stop layer pattern 138 and a portion of the first sacrificial layer 131 that is not covered with the second etch stop layer pattern 139 are removed so that a second sacrificial layer pattern 140 and a first sacrificial layer pattern 141 may be formed.

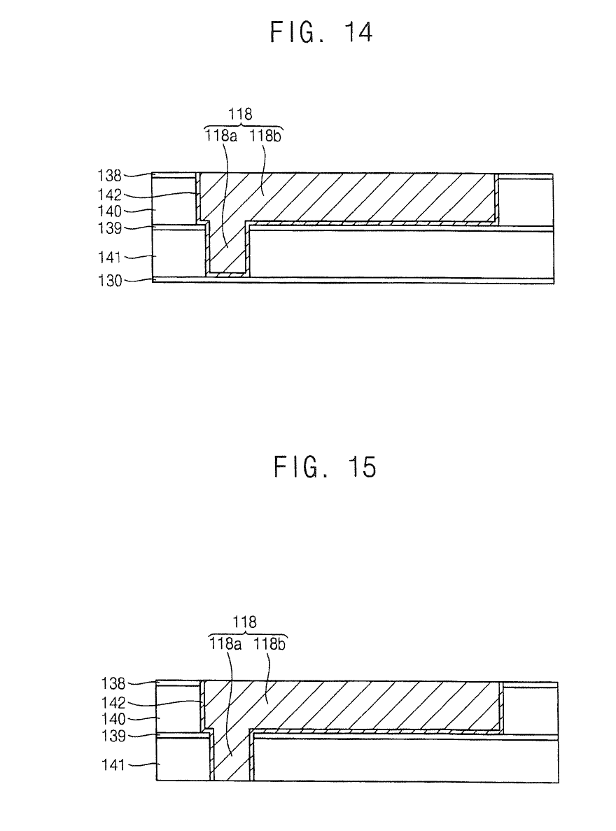

Referring to FIG. 14, a seed layer 142 having an uniform thickness may be formed on the mask layer pattern 137, the third etch stop layer pattern 138, the second sacrificial layer pattern 140, the second etch stop layer pattern 139, the first sacrificial layer pattern 141 and the first etch stop layer 130.

Thereafter, the mask layer pattern 137 is removed from the third etch stop layer pattern 138. Thus, a portion of the seed layer formed on the mask layer pattern 137 may be removed. Thereafter, a conductive material is deposited on the seed layer 142 to form the body integrally including the bump 118a and the beam 118b.

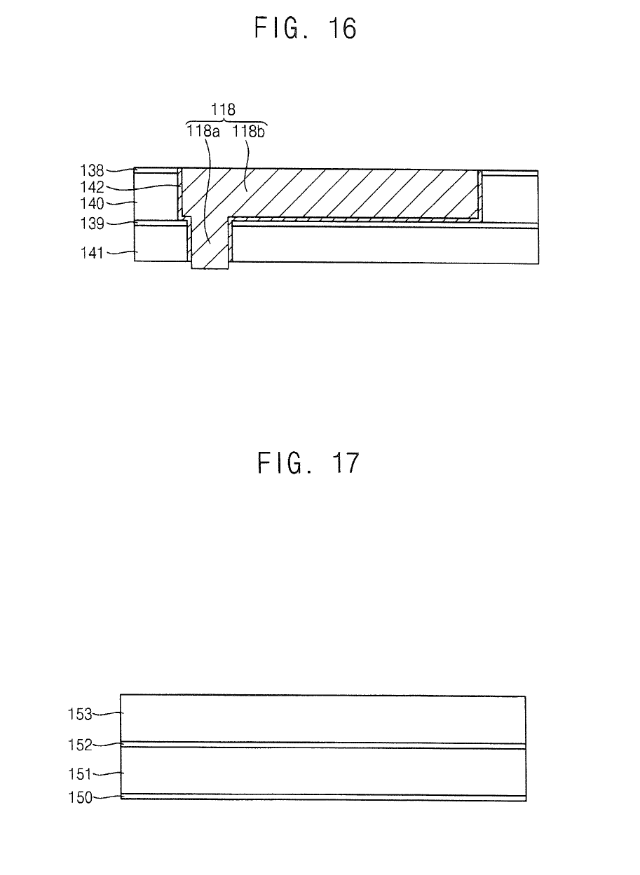

Referring to FIG. 15, a planarization process is performed on the first etch stop layer 130, the seed layer 142 and the first sacrificial layer pattern 141. The first etch stop layer 130 may be completely removed by the planarization process. The seed layer 142 and the first sacrificial layer pattern 141 are partially removed by the planarization process. Thus, the bump 118a may be exposed. As a result, a body structure 120 inside which the body 118 is located may be formed. The bump 118a may be exposed from a lower surface of the body structure 120. The beam 118b may be exposed from an upper surface of the body structure 120.

Referring to FIG. 16, an etching process is performed on the lower surface of the body structure 120 so that the first sacrificial layer pattern 141 and the seed layer 142 may be partially removed. The bump 118 may be partially protruded by the etching process. Here, the etching process is an optional process so that the etching process may be omitted.

FIGS. 17 to 23 are cross-sectional views illustrating a method of forming the body structure in accordance with still another example embodiment of the present invention.

Referring to FIG. 17, a first etch stop layer 150, a first sacrificial layer 151, a second etch stop layer 152 and a second sacrificial layer 153 are subsequently formed.

Referring to FIG. 18, the second sacrificial layer 153, the second etch stop layer 152 and the first sacrificial layer 151 are etched so that a preliminary second sacrificial layer pattern 154, a second etch stop layer pattern 155 and a first sacrificial layer pattern 156 may be formed.

Here, the preliminary second sacrificial layer pattern 154, the second etch stop layer pattern 155 and the first sacrificial layer pattern 156 together have a first hole 46 exposing the first etch stop layer 150. The first hole 46 may extend in a vertical direction.

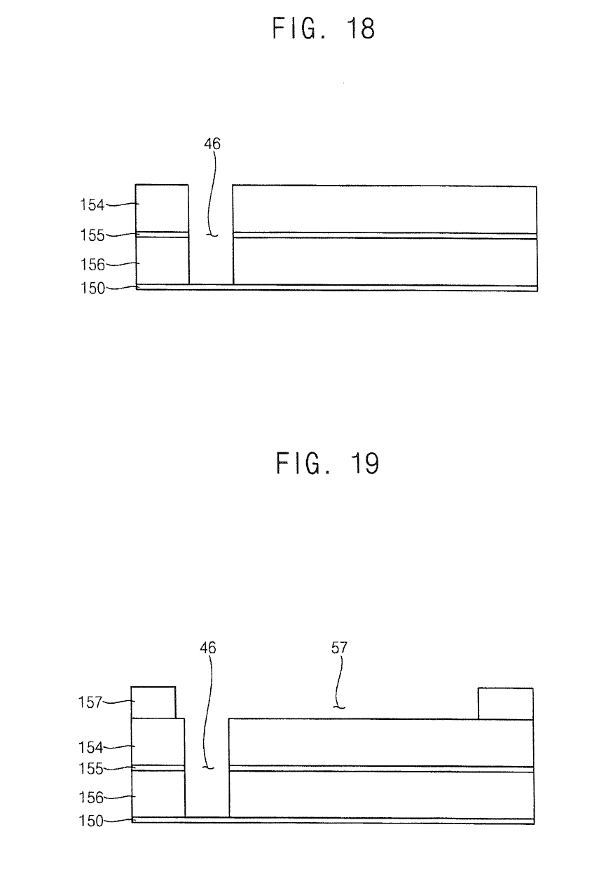

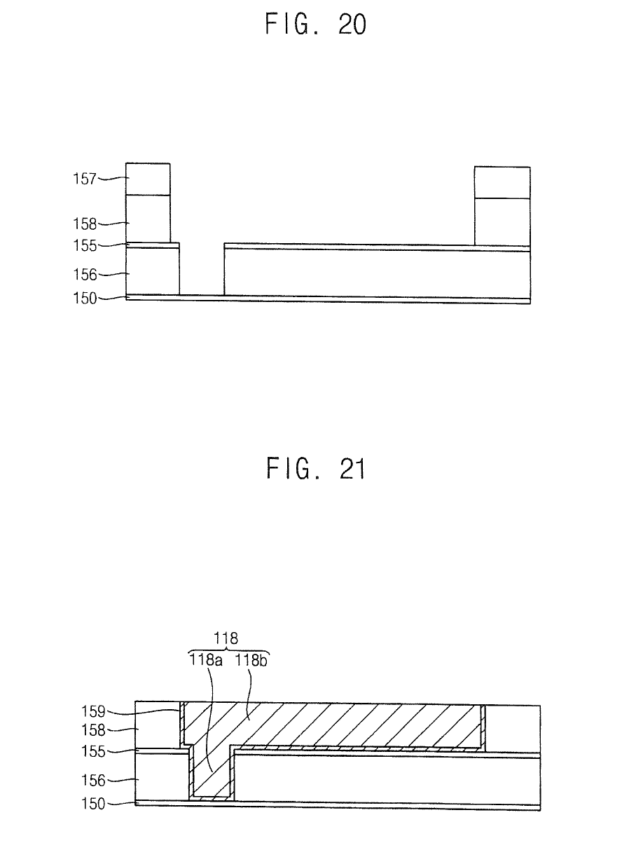

Referring to FIG. 19, a mask layer pattern 157 is formed on the preliminary second sacrificial layer pattern 154. The mask layer pattern 157 has a second hole 57 communicated with the first hole 46. The second hole 57 may extend in a horizontal direction.

Referring to FIG. 20, a portion of the preliminary third sacrificial layer pattern 154 exposed through the second hole 57 is removed so that a second sacrificial layer pattern 158 may be formed.

Referring to FIG. 21, a seed layer 159 having a uniform thickness is formed on the mask layer pattern 157, the second sacrificial layer pattern 158, the second etch stop layer pattern 155, the first sacrificial layer pattern 156 and the first etch stop layer 150. The mask layer pattern 157 is then removed from the second sacrificial layer pattern 158. Here, a portion of the seed layer 159 located on the mask layer pattern 157 may be removed together with the mask layer pattern 157. Thereafter, a conductive material is deposited on the seed layer 159 so that a body 118 integrally including the bump 118a and the beam 118b may be formed.

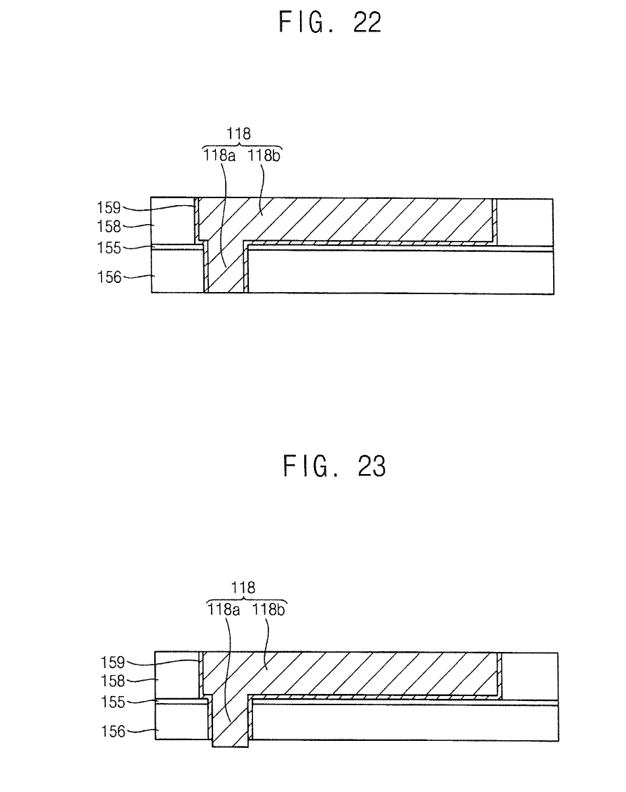

Referring to FIG. 22, a planarization process is performed on the first etch stop layer 150, the seed layer 158 and the first sacrificial layer pattern 156 [symbol] planarization process. The first etch stop layer 150 may be completely removed by the planarization process. The seed layer 158 and the first sacrificial layer pattern 156 are partially removed by the planarization process. Thus, the bump 118b may be exposed. As a result, a body structure 120 inside which the body 118 is located may be formed. The bump 118a may be exposed from a lower surface of the body structure 120. The beam 118b may be exposed from an upper surface of the body structure 120.

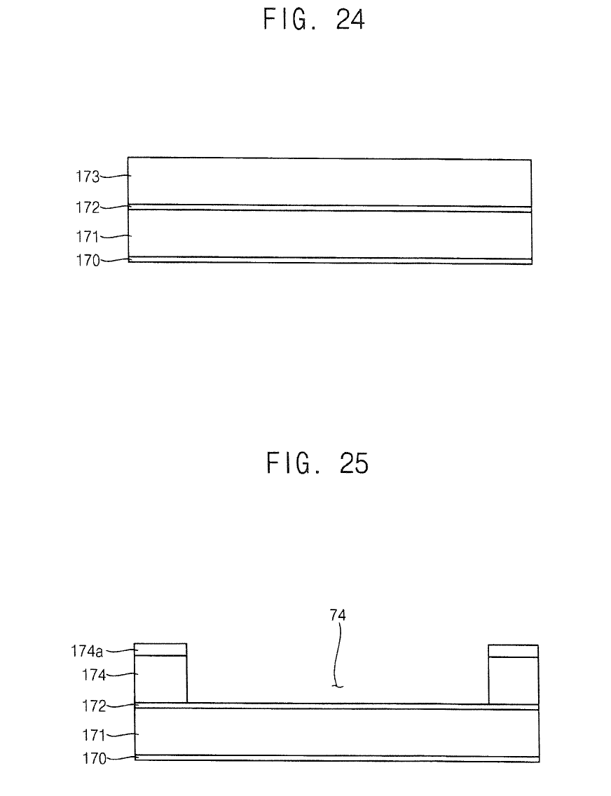

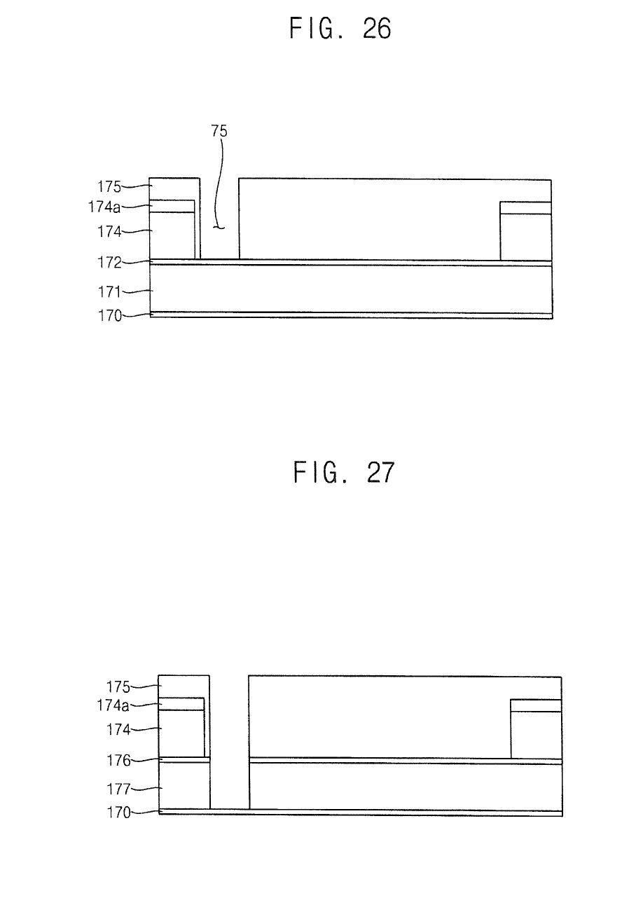

Referring to FIG. 23, an etching process is performed on the lower surface of the body structure 120 so that the first sacrificial layer pattern 156 and the seed layer pattern 159 may be partially removed. The bump 118a may be partially protruded by the etching process. The etching process is an optional process so that the etching process may be omitted.

FIGS. 24 to 30 are cross-sectional views illustrating a method of forming a body structure in accordance with still another example embodiment of the present invention.

Referring to FIG. 24, a first etch stop layer 170, a first sacrificial layer 171, a second etch stop layer 172 and a second sacrificial layer 173 are subsequently formed.

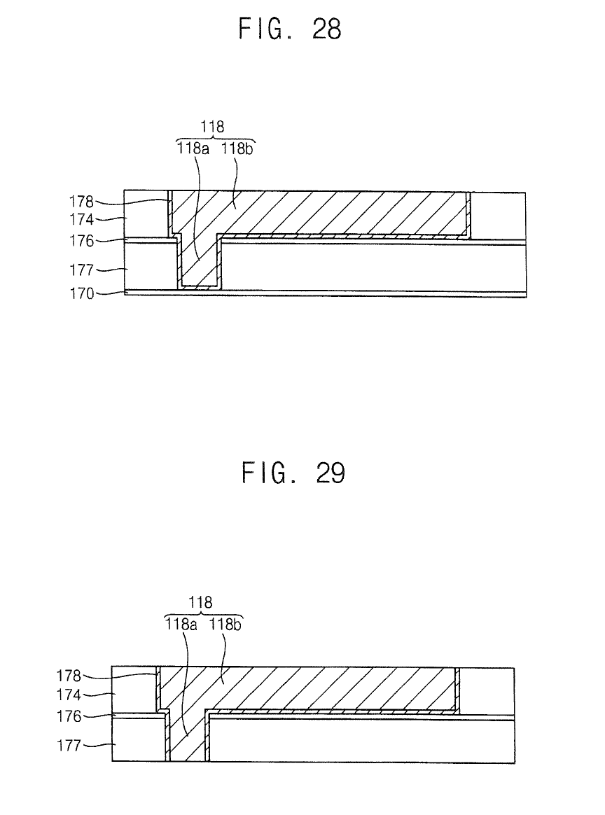

Referring to FIG. 25, a first mask layer pattern 174a is formed on a second sacrificial layer 173. Thereafter, the second sacrificial layer 173 may be etched using the first mask layer pattern 174a as an etch mask until the second etch stop layer 172 is exposed. Thus, a second sacrificial layer pattern 174 is formed. The second sacrificial layer pattern 174 has a first hole 74 extending in a horizontal direction.

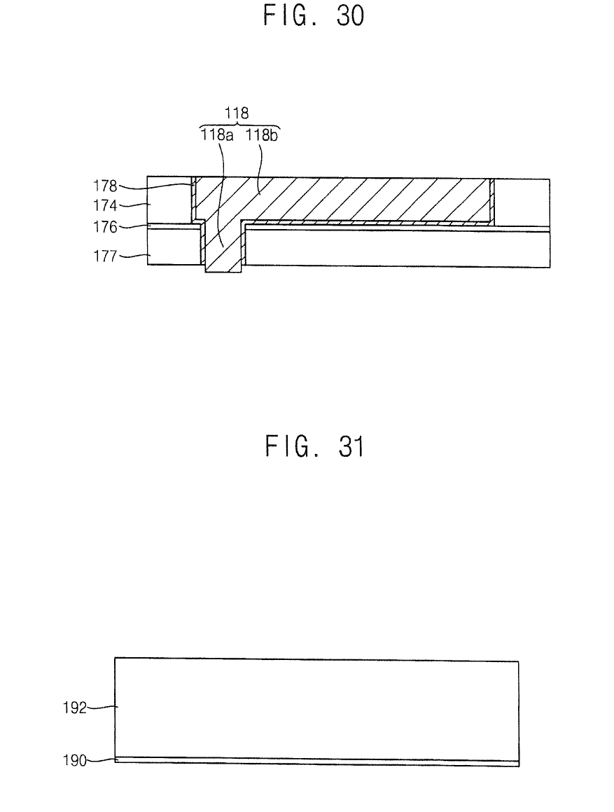

Referring to FIG. 26, a second mask layer pattern 175 having a second hole 75 partially exposing the second etch stop layer 172 is formed on the first mask layer pattern 174a, the second sacrificial layer pattern 174 and the second etch stop layer 172.

Referring to FIG. 27, the second etch stop layer 172 and the first sacrificial layer 171 are etched using the second mask layer pattern 175 as an etch mask until the first etch stop layer 170 is exposed. Thus, the second etch stop layer 172 and the first sacrificial layer 171 may be transformed into a second etch stop layer pattern 176 and a first sacrificial layer pattern 177, respectively.

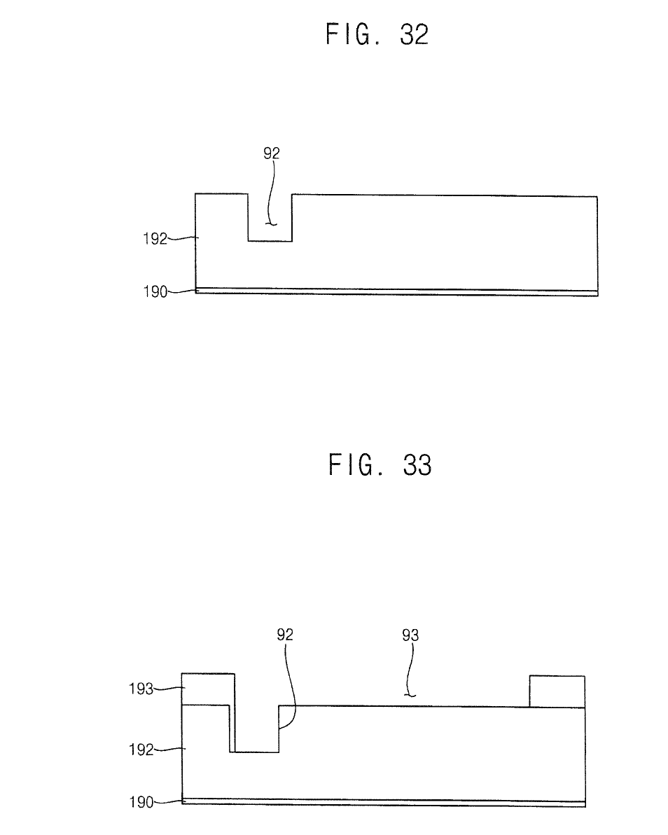

Referring to FIG. 28, the second mask layer pattern 175 is removed from the first mask layer pattern 174a, the second sacrificial layer pattern 174 and the second etch stop layer pattern 176. Thereafter, a seed layer 178 having a uniform thickness is formed on the second mask layer pattern 175, the second sacrificial layer pattern 174, the second etch stop layer pattern 176, the first sacrificial layer pattern 177 and the first etch stop layer 170. The first mask layer pattern 174a is then removed. Here, a portion of the seed layer 178 located on the first mask layer pattern 174a may be also removed.

Thereafter, a conductive material is deposited on the seed layer 178 so that the body 118 including the bump 118a and the beam 118b may be formed.

Referring to FIG. 29, a planarization process is performed on the first etch stop layer 170, the seed layer 178 and the first sacrificial layer pattern 177. The first etch stop layer 170 may be completely removed by the planarization process. The seed layer 178 and the first sacrificial layer pattern 177 are partially removed. Thus, the bump 118a may be exposed. As a result, a body structure 120 inside which the body 118 is located may be formed. The beam 118b may be exposed from a lower surface of the body structure 120. The bump 118a may be exposed from an upper surface of the body structure 120.

Referring to FIG. 30, an etching process is performed on the lower surface of the body structure 120 so that the first sacrificial layer pattern 177 and the seed layer 178 may be partially removed. The bump 118a may be partially protruded from the etching process. Here, the etching process is an optional process so that the etching process may be omitted.

FIGS. 31 to 36 are cross-sectional views illustrating a method of forming a body structure in accordance with still another example embodiment of the present invention.

Referring to FIG. 31, an etch stop layer 190 and a sacrificial layer 192 are subsequently formed.

Referring to FIG. 32, a first anisotropic etching process is performed on the sacrificial layer 192 to form a recess 92. A sidewall of the recess 92 may be relatively vertical because the recess 92 is formed by the first anisotropic etching process.

Referring to FIG. 33, a mask layer pattern 193 may be formed on the sacrificial layer 192. The mask layer pattern 193 has a hole 93 communicated with the recess 92. The hole 93 may extend in a horizontal direction.

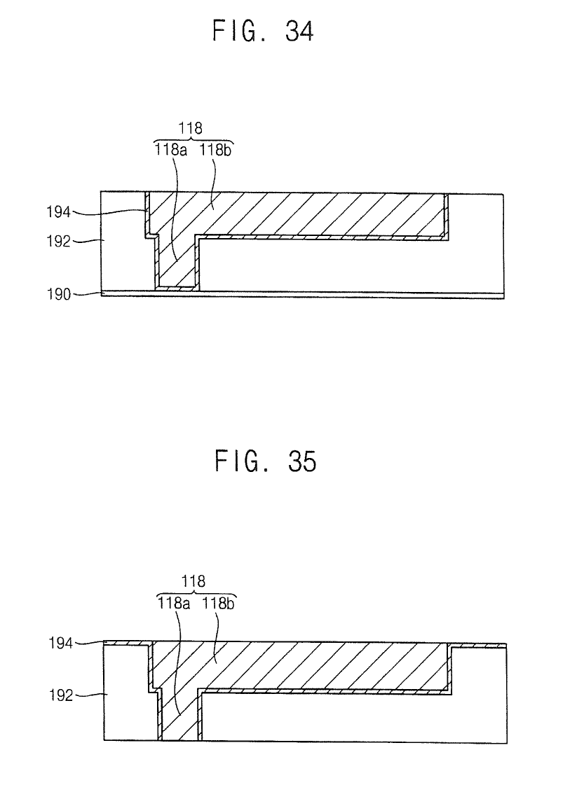

Referring to FIG. 34, a second anisotropic etching process is performed on a portion of the sacrificial layer 192 exposed through the hole 93 until the etch stop layer 190 is exposed. Thus, the portion of the sacrificial layer 192 exposed through the hole 93 may uniformly decrease.

The mask layer pattern 193 may be removed from the sacrificial layer 192. A seed layer 194 having a uniform thickness is formed on the sacrificial layer 192. Thereafter, the body 118 integrally including the bump 118 and the beam 118b is formed on the seed layer 194.

Referring to FIG. 35, a planarization process is performed on the etch stop layer 190, the seed layer 194 and the sacrificial layer 192. The etch stop layer 190 is removed by the planarization process. The seed layer 194 and the sacrificial layer 192 are partially removed by the planarization process. Thus, the bump 118a may be exposed. As a result, a body structure 120 inside which the body 118 is located is formed. The bump 118a may be exposed from a lower surface of the body structure 120. The beam 118b may be exposed from an upper surface of the body structure 120.

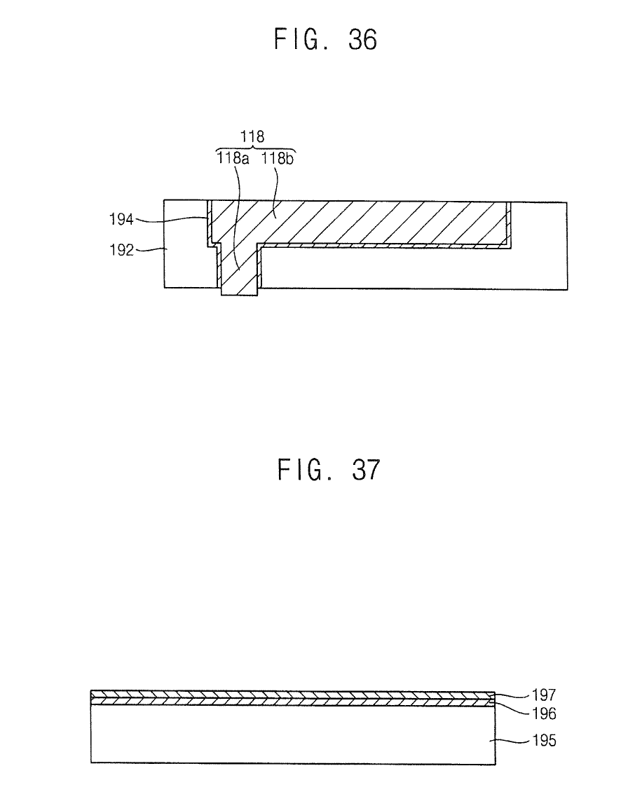

Referring to FIG. 36, an etching process is performed on the lower surface of the body structure 120 so that the first sacrificial layer pattern 192 and the seed layer 194 may be partially removed. The etching process is an optional process so the etching process may be omitted.

FIGS. 37 to 40 are cross-sectional views illustrating a method of forming a body structure in accordance with still another example embodiment of the present invention.

Referring to FIG. 37, a seed layer 196 is formed on a sacrificial layer 195 such as a silicon substrate. Thereafter, a metal such as copper is deposited on the seed layer 196 so that a separation layer 197 may be formed.

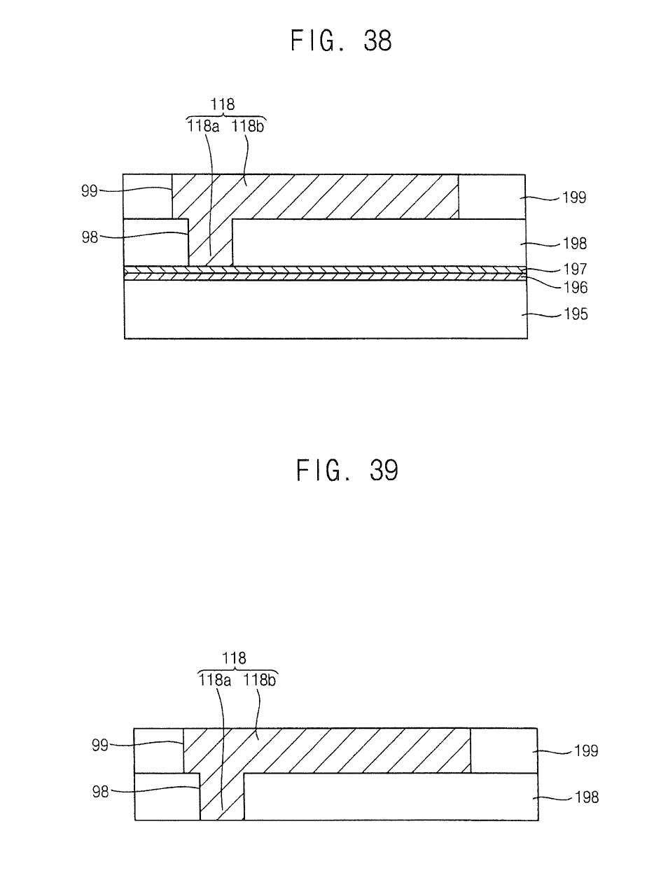

Referring to FIG. 38, a first photoresist layer pattern 198 having a first hole 98 is formed on the separation layer 197. A second photoresist layer pattern 199 is then formed on the first photoresist layer pattern 198. The second photoresist layer pattern 199 has a second hole 99 communicated with the first hole 98. The second hole 99 may have a width substantially larger than that of the first hole 98.

The body 118 filling up the first and second holes 98 and 99 are formed by a deposition process such as an electroplating process. Particularly, the bump 118a of the body 118 may be formed in the first hole 98. The beam 118b of the body 118 is formed in the second hole 99.

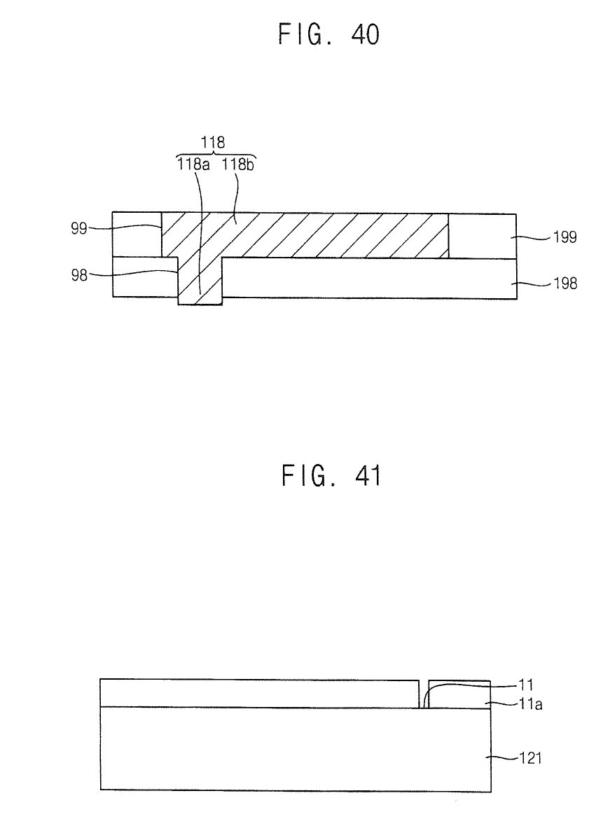

Referring to FIG. 39, the separation layer 197 is removed. Thus, the sacrificial layer 195 and the seed layer 196 are separated so that the sacrificial layer 195 and the seed layer 196 may be removed. As a result, a body structure 120 inside which the body 118 is located may be formed. The bump 118a is exposed from a lower face of the body structure 120. The beam 118b is exposed from an upper face of the body structure 120.

Referring to FIG. 40, an etching process is performed on the lower surface of the body structure 120 so that the first photoresist layer pattern 198 may be partially removed. The bump 118a may be partially protruded by the etching process. Here, the etching process is an optional process. Thus, the etching process may be omitted.

FIGS. 41 to 47 are cross-sectional views illustrating a method of forming a tip structure in accordance with an embodiment of the present invention.

Referring to FIG. 41, a sacrificial layer 121 including a semiconductor material such as silicon may be provided. Thereafter, a first mask layer pattern 11a having a hole exposing a first surface region of the sacrificial layer 121 is formed.

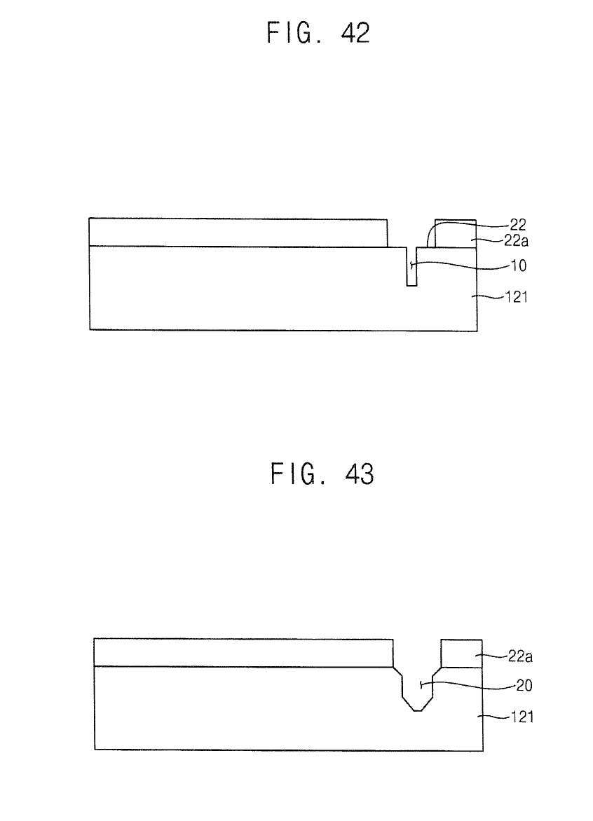

Referring to FIG. 42, a first anisotropic etching process is performed on the first surface region 11 so that a first recess 10 may be formed. Thereafter, the first mask layer pattern 11a is removed. A second mask layer pattern 22a is formed on the sacrificial layer 121. The second mask layer pattern 22a having a hole exposing a second surface region 22 of the sacrificial layer 121 enclosing the first surface region 11 where the first recess 10 is formed is formed on the sacrificial layer 121.

Referring to FIG. 43, an isotropic etching process is performed on the second surface region 22 so that the first recess 10 may be transformed into a second recess 20. The second recess 20 may have a width substantially larger than that of the first recess 10. The second recess 20 may have a depth substantially larger than that of the first recess 10. Folded portions formed at the second surface region 22 are removed by the isotropic etching process so that the second recess 20 may have a lower end portion more sharpened than that of the first recess 10.

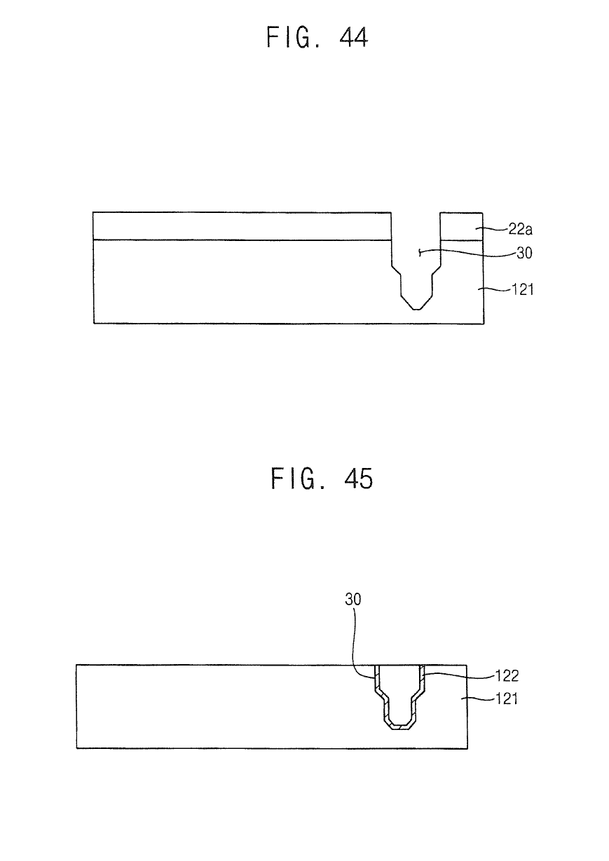

Referring to FIG. 44, a second anisotropic etching process is performed on the second surface region 22 to uniformly reduce the height of the second surface region 22. Thus, the second recess 20 may be transformed into a third recess 30 having a depth substantially larger than that of the second recess 20.

Referring to FIG. 45, a seed layer 122 having a uniform thickness is formed on the second mask layer pattern 20 and the sacrificial layer 121 such that the seed layer 122 may be conformed to an inner face of the third recess 30. Thereafter, the second mask layer pattern 20 may be removed from the sacrificial layer 121. Here, a portion of the seed layer 122 located on the second mask layer pattern 20 is also removed.

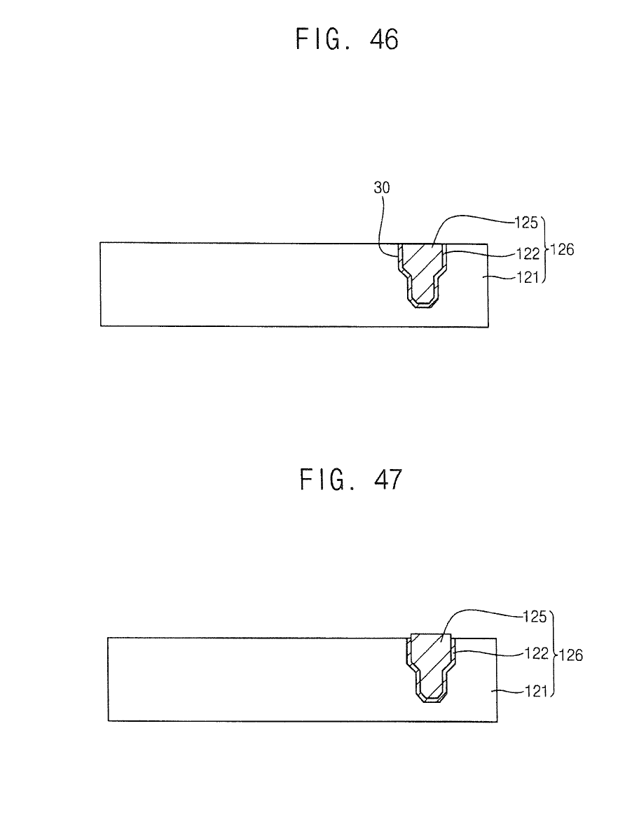

Referring to FIG. 46, a conductive material is deposited on the seed layer 112 by a deposition process such as an electroplating process, a physical vapor deposition process and a chemical vapor deposition process to form a tip 125. Thus, a tip structure 126 inside which the tip 125 is located may be formed. The tip 125 is exposed from a surface of the tip structure 126.

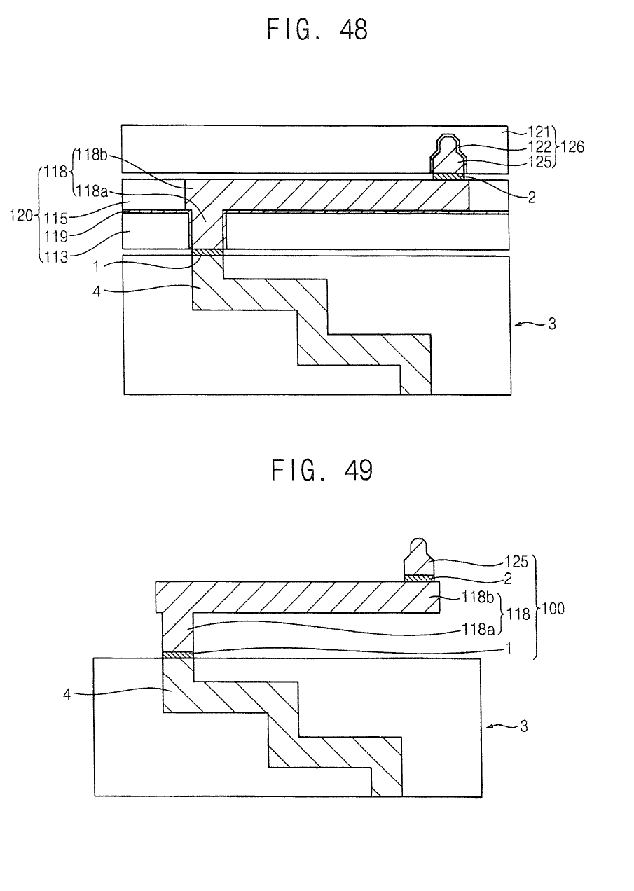

Referring to FIG. 47, an etching process is performed on the tip structure 126 to partially remove the sacrificial layer 121 and the seed layer 122. The tip 125 may be partially removed by the etching process. Here, the etching process is an optional process so that the etching process may be omitted.

The tip structure may be formed by the above method. However, the tip structure may be formed by various methods.

As one example, the first surface region of the sacrificial layer is anisotropically etched so that a first recess may be formed. A second surface region of the sacrificial layer enclosing the first surface region where the first recess is formed is exposed. Here, the second surface region may have an area substantially larger than that of the first surface region. Thereafter, the second surface region is anisotropically etched so that the first recess may be transformed into the second recess. Thereafter, a third surface region of the sacrificial layer enclosing the second surface region where the second recess is exposed. Here, the third surface region may have an area substantially larger than that of the second surface region. The third surface region is then anisotropically etched to transform the second recess into a third recess. Thereafter, a seed layer having a uniform thickness is formed on the sacrificial layer such that the seed layer may be conformed to an inner face of the third recess. A tip is then formed on the seed layer. An etching process partially removing the seed layer and the sacrificial layer may be performed so that the tip may be partially protruded.

As another example, a first region of the sacrificial layer is anisotropically etched to form a first recess. A second region of the sacrificial layer encloses the first surface region where the first recess is then exposed. The second region may have an area substantially larger than that of the first region. Thereafter, the second surface region is isotropically etched to transform the first recess into a second recess. A seed layer having a uniform thickness is then formed on the sacrificial layer such that the seed layer may be conformed to an inner face of the second recess. Thereafter, a tip is formed on the seed layer. An etching process partially removing the seed layer and the sacrificial layer may be performed so that the tip may be partially protruded.

As yet another example, a first surface region is isotropically etched to form a recess. A photoresist layer pattern is formed on the sacrificial layer. The photoresist layer pattern has a hole exposing a second surface region enclosing the first surface region where the recess is formed. The second surface region has an area substantially larger than that of the first surface region. A seed layer having a uniform thickness is formed on the sacrificial layer and the photoresist layer pattern such that the seed layer may be conformed to inner faces of the hole and the recess. Thereafter, a tip is formed on the seed layer. An etching process partially removing the seed layer and the sacrificial layer may be performed so that the tip may be partially protruded.

Hereinafter, a method of fixing the body structure and the tip structure formed by the above methods is described.

Referring to FIG. 48, a first connecting member 1 is formed between a wire 4 included in an electric component 3 and the bump 118a of the body 118 included in the body structure 120. The first connecting member 1 may physically and electrically connect the bump 118a of the body 118 to the wire 4 of the electric component 3. The first connecting member 1 may include a conductive material such as lead. In addition, the first connecting member 1 may be formed by a screen printing method.

In the case in which the bump 118a is partially protruded by the etching process illustrated in FIG. 8, 16, 23, 30, 36 or 40, an interval between the body structure 120 and the electric component 3 may increase. Thus, the first connecting member 1 may be effectively formed.

A second connecting member 2 is formed between the tip 125 included in the tip structure 126 and the beam 118b of the body 118 included in the body structure 120. The second connecting member 2 may physically and electrically connect the tip 125 to the beam 118b. The second connecting member 2 may include a conductive material such as lead. In addition, the second connecting member 2 may be formed by a screen printing process.

Here, in a case in which the tip 125 is partially protruded by the etching process illustrated in FIG. 47, an interval between the tip structure 126 and the body structure 120 may increase. Thus, the second connecting member 2 may be effectively formed.

As described above, a second connecting member 2 may be formed after the first connecting member 1 is formed. As one alternative, the first connecting member 1 is formed after the second connecting member 2 is formed. As another alternative, the first connecting member 1 and the second connecting member 2 may be formed at the same time.

Although not particularly illustrated in FIG. 48, the wire 4 of the electric component 3 may be connected to a printed circuit board (PCB) located under the electric component 3.

Referring to FIG. 49, a portion of the body structure 120 except for the body 118 and a portion of the tip structure 126 except for the tip 125 are removed. As a result, a probe 100 including the first connecting member 1, the body 118, the second connecting member 2 and the tip 125 may be formed.

FIG. 50 is a cross-sectional view illustrating a probe 200 in accordance with an embodiment of the present invention.

Referring to FIG. 50, the probe 200 may include a first connecting member 1, a body 118 and a tip 225. The first connecting member 1 and the body 118 are already explained in FIG. 2. Thus, a repetitive explanation will be omitted.

The tip 225 is directly formed on the beam 118b of the body 118. That is, a connecting member or a conductive pad may not be formed between the tip 225 and the body 118.

The tip 225 extends on the beam 118b of the body 118 in a vertical direction. The tip 225 may have a stepped shape such that the width of the tip 225 becomes smaller in a direction from a portion of the tip 225 connected to the beam 118b toward a portion of the tip 225 making contact with a pad of a semiconductor chip. In this case, the tip 225 may include 1^{st} to n^{th} (“n” is a natural number larger than “1”.) conductive members subsequently stacked on the beam 118b of the body 118. Here, a width of m^{th} (“m is a natural number larger than “n”.) conductive member may be larger than that of (m+1)^{th} conductive member.

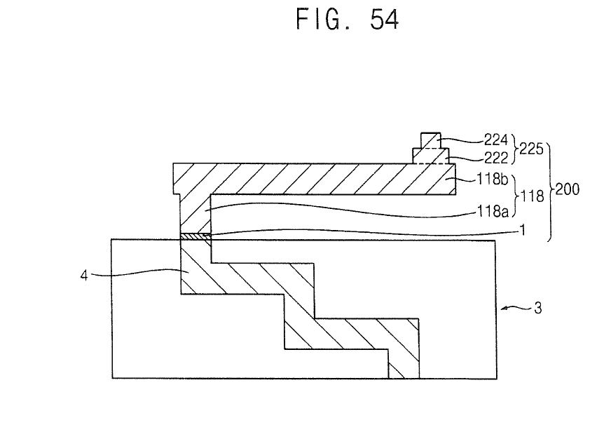

For example, as illustrated in FIG. 54, the tip 225 may include a first conductive member 222 and a second conductive member 224. The first conductive member 222 is located on the beam 118b of the body 118. The second conductive member 224 is located on the first conductive member 222. The second conducive member 224 may have a width substantially lower than that of the first conductive member 222.

Alternatively, the first conductive member 222 may be alone as the tip 225.

Hereinafter, a method of manufacturing the probe 200 in FIG. 50 is described.

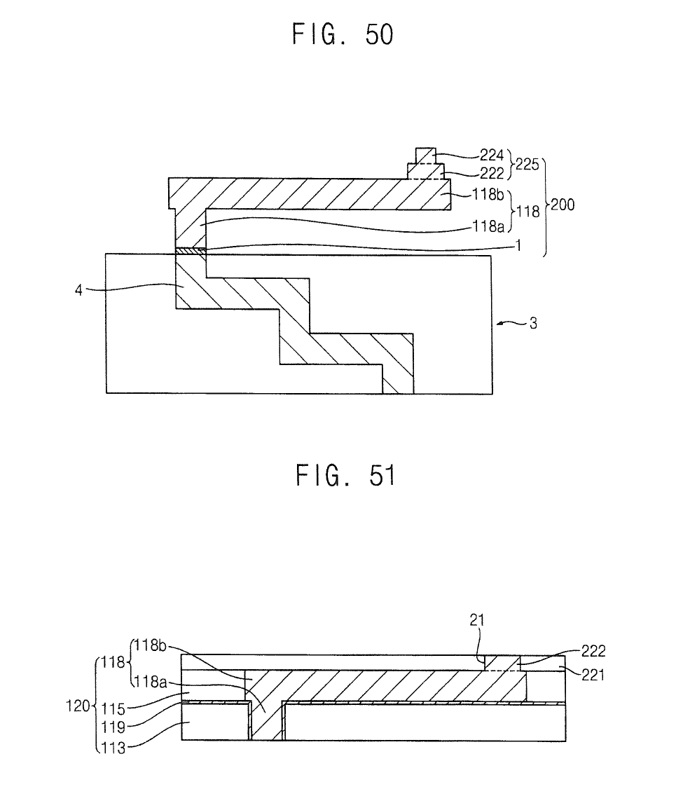

FIGS. 51 to 56 are cross-sectional views illustrating a method of manufacturing the probe 200.

The body structure 120 formed by processes illustrated in FIGS. 3 to 8 is employed in FIGS. 51 to 56 for convenience of explanation. However, the body structure 120 formed by processes illustrated in FIGS. 17 to 23, the body structure 120 formed by processes illustrated in FIGS. 24 to 30 and the body structure 120 formed by processes illustrated in FIGS. 31 to 36 may be employed to form the probe 200.

The tip structure 227 including the tip and the photoresist structure 226 is directly formed on the body structure 120. The tip 225 may have a stepped shape such that the width of the tip 225 becomes narrow in a direction from a portion of the tip 225 connected to the beam 118b toward a portion of the tip 225 making contact with a pad of a semiconductor chip. In this case, the tip 225 may include 1^{st} to n^{th} (“n” is a natural number larger than “1”.) conductive members. The photoresist structure 226 may include 1^{st} to n^{th} photoresist layer patterns enclosing sidewalls of 1^{st} to n^{th} conductive members, respectively. Here, a width of m^{th} (“m” is a natural number larger than “n”.) conductive member may be larger than that of (m+1)^{th} conductive member.

The conductive members may include a conductive material such as metal or alloy. The conductive material may be nickel, nickel-cobalt or nickel-cobalt-tungsten.

For example, referring to FIG. 51, a first photoresist layer pattern 221 is formed on the body structure 120. The first photoresist layer pattern 221 may have a first opening 21 exposing the beam 118b of the body 118.

A first conductive member 222 filling up the first opening 21 of the first photoresist layer pattern 221 is formed by an electroplating process, a chemical vapor deposition process or a physical vapor deposition process.

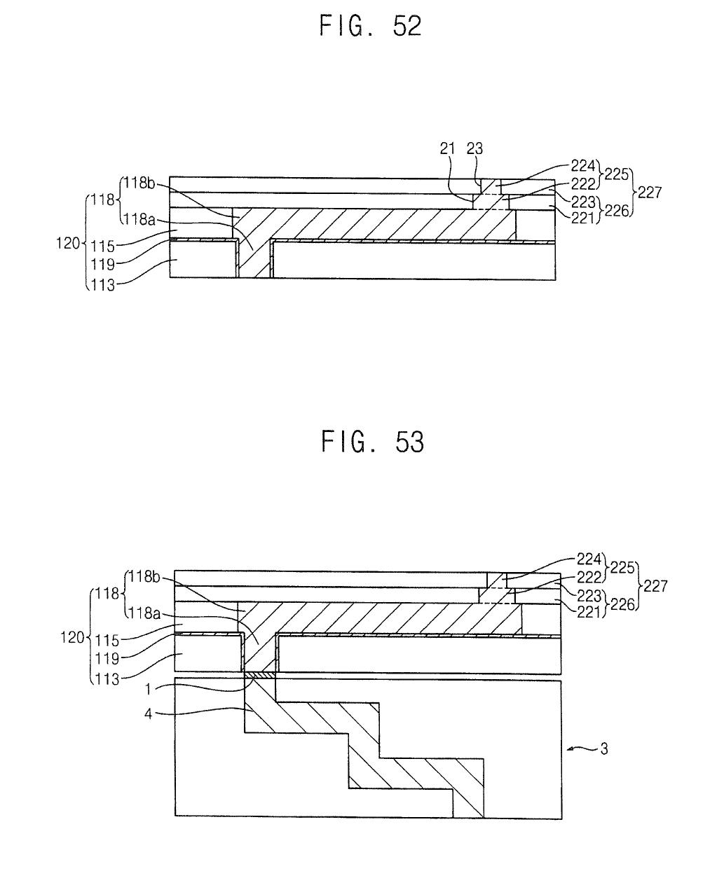

Referring to FIG. 52, a second photoresist layer pattern 223 is formed on the first photoresist layer pattern 221 and the first conductive member 222. The second photoresist layer pattern 223 has a second opening 23 exposing the first conductive member 222. The width of the second opening 23 is substantially smaller than that of the first opening 21.

A second conductive member 224 filling up the second opening 23 of the second photoresist layer pattern 223 is formed by a deposition process such as an electroplating process, a chemical vapor deposition process or a physical vapor deposition process.

Thus, a tip structure 227 including a tip 225 and a photoresist structure 226 may be formed. The tip 225 may include the first conductive member 222 and the second conductive member 224. The photoresist structure 226 may include the first photoresist layer pattern 221 and the second photoresist layer pattern 223.

Alternatively, only the first photoresist layer pattern 221 and the first conducive member 222 may be formed. In this case, the first photoresist layer pattern 221 and the first conductive member 222 may correspond to the photoresist structure 226 and the tip 225, respectively.

Referring to FIG. 53, a first connecting member 1 is formed between the wire 4 of the electric component 3 and the bump 118a of the body 118 included in the body structure 120 after the tip structure 227 is formed.

Referring to FIG. 54, a portion of the body structure 120 except for the body 118 and the photoresist structure 226 of the tip structure 227 may be removed. Thus, the probe 200 including the first connecting member 1, the body 118 and the tip 225 may be formed.

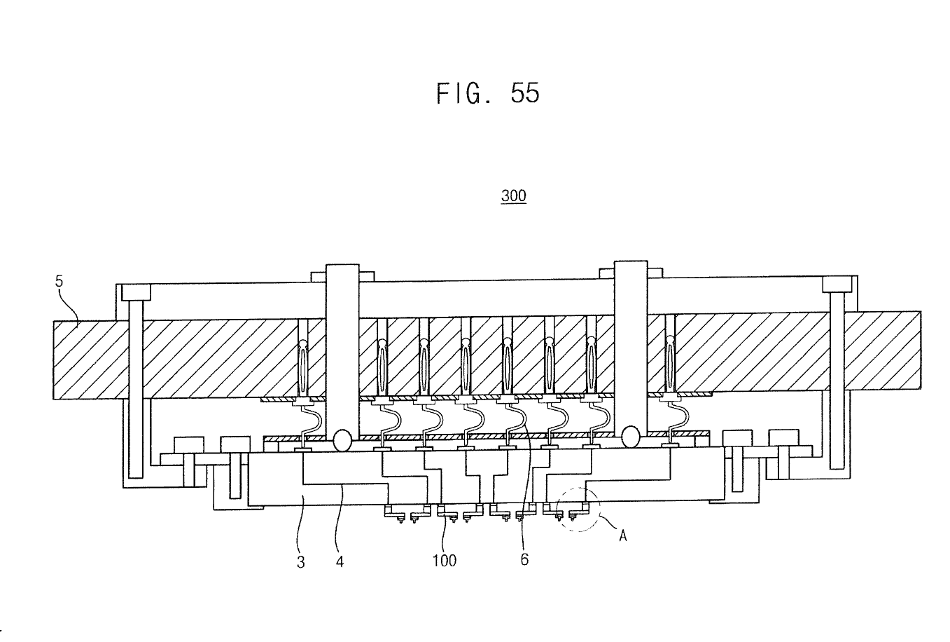

FIG. 55 is a cross-sectional view illustrating a probe card in accordance with an embodiment of the present invention.

Referring to FIG. 55, the probe card 300 may include a printed circuit board 5, a connector 6, an electric component 5 and a probe 100. The printed circuit board 5 may include circuit traces of various electric units used to electrically test a programmed semiconductor chip. The connector 6 has elasticity in a vertical direction. The connector 6 may connect the printed circuit board 5 to the electric component 3. A wire 4 may be formed inside the electric component 3 to reduce a pitch distance.

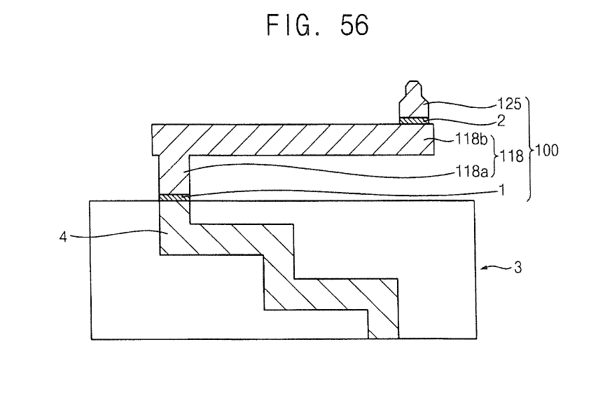

FIG. 56 is an enlarged cross-sectional view of a portion “A” in FIG. 55.

Referring to FIG. 56, the probe 100 in the probe card 300 may be substantially the same as that in FIG. 2.

Particularly, the probe 100 may include a first connecting member 1, a body 118, a second connecting member 2 and a tip 125. The body 118 may integrally include the bump 118a extending in a vertical direction and the beam 118b extending in a horizontal direction. Here, the bump 118a and the beam 118b may be formed as one body having a substantially reversed “L” shape.

The first connecting member 1 may be formed between the wire 4 of the electric component 3 and the bump 118a of the body 118 to fix the body 118 to the electric component 3. The second connecting member 2 may be formed between the beam 118b of the body 118 and the tip 125 to fix the tip 125 to the beam 118b. The tip 125 may extend in a vertical direction on the second connecting member 2.

The tip 125 may make contact with the pad of a semiconductor chip to inspect the semiconductor chip. Thus, a width of the tip 125 may decrease in a direction from a portion of the tip 125 connected to the beam 118b toward a portion of the tip 125 making contact with the pad of the semiconductor chip.

The body 118 integrally including the bump 118a and the beam 118b may provide elasticity when the tip 125 makes contact with the pad of the semiconductor chip. Thus, the beam 118b may be spaced apart from the electric component by the bump 118a.

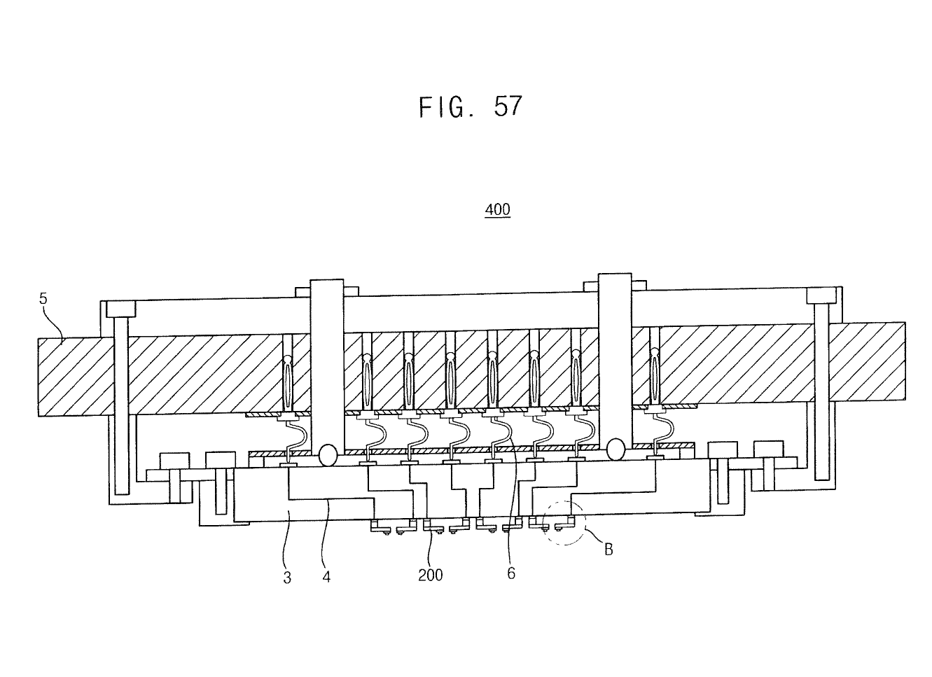

FIG. 57 is a cross-sectional view illustrating a probe card 400 in accordance with an embodiment of the present invention.

Referring to FIG. 57, the probe card 400 may include a printed circuit board 5, a connector 6, an electric component 5 and a probe 200.

The printed circuit board 5 may include circuit traces of various electric units used to electrically test a programmed semiconductor chip. The connector 6 has elasticity in a vertical direction. The connector 6 may connect the printed circuit board 5 to the electric component 3. A wire 4 may be formed inside the electric component 3 to reduce pitch distance.

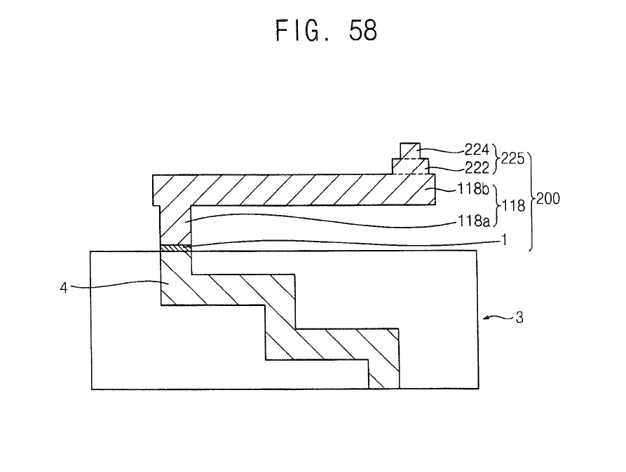

FIG. 58 is an enlarged cross-sectional view of a portion “B” in FIG. 57.

Referring to FIG. 58, the probe 100 in the probe card 400 may be substantially the same as that in FIG. 54.

Particularly, the probe 200 may include a first connecting member 1, a body 118, a second connecting member 2 and a tip 225. The body 118 may integrally include the bump 118a extending in a vertical direction and the beam 118b extending in a horizontal direction. Here, the bump 118a and the beam 118b may be formed as one body having a substantially reversed “L” shape.

The first connecting member 1 is formed between the wire 4 and the bump 118a of the body 118 to fix the electric component 3 to the body 118. The second connecting member 2 is formed between the beam 118b of the body 118 and the tip 125 to fix the tip 125 to the beam 118b.

The tip 225 may extend in a vertical direction on the beam 118b of the body 118. The tip 225 may have a stepped shape such that a width of the tip 225 becomes smaller in a direction from a portion of the tip 225 connected to the beam 118b toward a portion of the tip 225 making contact with a pad of a semiconductor chip.

In this case, the tip 225 may include 1^{st} to n^{th} (“n” is a natural number larger than “1”.) conductive members subsequently stacked on the beam 118b of the body 118. Here, a width of m^{th} (“m is a natural number larger than “n”.) conductive member may be larger than that of (m+1)^{th} conductive member.

For example, the tip 225 may include a first conductive member 222 and a second conductive member 224 having a first width and a second width, respectively. The first conductive member 222 is directly located on the beam 118b of the body 118. The second conductive member 224 is directly located on the first conductive member 222. The first width may be smaller than the second width. Alternatively, the first conducive member 222 alone may be used as the tip 225.

The body 118 integrally including the bump 118a and the beam 118b may provide elasticity when the tip 125 makes contact with the pad of the semiconductor chip. Thus, the beam 118b may be spaced apart from the electric component by the bump 118a.

According to the present invention, a bump and a beam are integrally formed. Thus, the yield and durability of a probe may be larger than that formed by a conventional process in which the bump and the beam are independently formed.

In addition, a performing a photolithography process directly on an electric component that is relatively expensive may not be necessary when the bump is formed. Thus, damage to the electric component may be reduced.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A probe comprising:
a first connecting member formed on an electric component to be electrically connected to the electric component;
a body integrally including a bump fixed to the electric component by the first connecting member and a beam connected to the bump such that the beam is spaced apart from the electric component; and
a tip formed on the beam, the tip making contact with a pad of a semiconductor chip to examine the semiconductor chip.

2. The probe of claim 1, further comprising a second connecting member located between the beam and the tip to eclectically connect the beam to the tip.

3. The probe of claim 1, wherein the tip has a stepped shape having a width becoming smaller in a direction from a portion of the tip connected to the beam toward a portion of the tip making contact with the pad of the semiconductor chip.

4. The probe of claim 1, wherein the bump and the beam are formed as one body having a substantially reversed “L” shape.

5. A probe card comprising:
a printed circuit board;
a electric component electrically connected to the printed circuit board; and
a probe including a first connecting member, a body and a tip, the first connecting member formed on the electric component to be connected to the electric component, the body integrally including a bump and a beam, the bump being fixed to the electric component by the first connecting member, the beam being connected to the bump such that the beam is spaced apart from the electric component, the tip formed on the beam, the tip making contact with a pad of a semiconductor chip to examine the semiconductor chip.

6. The probe card of claim 5, further comprising a second connecting member located between the beam and the tip to electrically connect the beam to the tip; and
wherein the tip has a stepped shape having a width becoming smaller in a direction from a portion of the tip connected to the beam toward a portion of the tip making contact with the pad of the semiconductor chip; and
wherein the bump and the beam of the body are formed as one body having a substantially reversed “L” shape.

7. A method of manufacturing a probe, the method comprising:
forming a body structure inside which a body integrally including a bump extending in a vertical direction and a beam extending in a horizontal direction such that the beam is connected to the bump, the bump being exposed from a lower surface of the body structure, the beam being exposed from an upper surface of the body structure;
forming a tip structure inside which a tip is formed, the tip being exposed from a lower surface of the tip structure;
forming a first connecting member between an electric component and the bump to connect the body structure to the electric component; and
removing a portion of the body structure except the body and a portion of the tip structure except for the tip.

8. The method of claim 7, further comprising forming a second connecting member between the beam and the tip to fix the tip structure to the body structure.

9. The method of claim 8, wherein forming the first connecting member is performed after the second connecting member is formed.

10. The method of claim 8, wherein forming the first connecting member is performed before the second connecting member is formed.

11. The method of claim 8, wherein forming the first connecting member is performed simultaneously with forming the second connecting member.

12. The method of claim 7, further comprising allowing the bump to be partially protruded by partially removing the lower surface of the body structure before the first connecting member is formed.

13. The method of claim 7, wherein forming the body structure comprises:
providing a sacrificial layer;
oxidizing a lower surface of the sacrificial layer to form an etch stop layer;
etching the sacrificial layer until the etch stop layer is exposed to form a sacrificial layer pattern having a hole extending in a vertical direction;
forming a seed layer having a relatively uniform thickness on the sacrificial layer pattern and the etch stop layer;
forming a photoresist pattern exposing the hole and a portion of the seed layer adjacent to the hole;
depositing a conductive material on the exposed portion of the seed layer to form the body; and
planarizing the etch stop layer, the seed layer and the sacrificial layer until the body is exposed.

14. The method of claim 7, wherein forming the body structure comprises:
subsequently forming a first etch stop layer, a first sacrificial layer, a second etch stop layer, a second sacrificial layer and a third etch stop layer;
etching the third etch stop layer and the second sacrificial layer until the second etch stop layer is exposed to form a preliminary third etch stop layer pattern and a preliminary second sacrificial layer pattern that define a first hole;
forming a mask layer pattern having a horizontally extending second hole communicated with the first hole on the preliminary third etch stop layer pattern;
etching a portion of the preliminary third etch stop layer pattern that is not covered with the mask layer pattern and a portion of the second etch stop layer that is not covered with the preliminary second sacrificial layer pattern to form a third etch stop layer pattern and a second etch stop layer pattern;
etching a portion of the preliminary third sacrificial layer pattern that is not covered with the third etch stop layer pattern and a portion of the first sacrificial layer that is not covered with the second etch stop layer pattern until the second etch stop layer pattern and the first etch stop layer are exposed to form a second sacrificial layer pattern and a first sacrificial layer pattern, respectively;
forming a seed layer having an uniform thickness on the mask layer pattern, the third etch stop layer pattern, the second sacrificial layer pattern, the second etch stop layer pattern, the first sacrificial layer pattern and the first etch stop layer;
removing the mask layer pattern;
depositing a conductive material on the seed layer to form the body; and
planarizing the first etch stop layer, the seed layer and the first sacrificial layer pattern until the body is exposed.

15. The method of claim 7, wherein forming the body structure comprises:
subsequently forming a first etch stop layer, a first sacrificial layer, a second etch stop layer and a second sacrificial layer;
etching the second sacrificial layer, the second etch stop layer and the first sacrificial layer until the first etch stop layer is exposed to form a preliminary second sacrificial layer pattern, a second etch stop layer pattern and a first sacrificial layer pattern that define a vertically extending first hole;
forming a mask layer pattern having a horizontally extending second hole communicated with the first hole on the preliminary second sacrificial layer pattern;
removing a portion of the preliminary second sacrificial layer pattern exposing through the second hole to form a second sacrificial layer pattern;
forming a seed layer having a relatively uniform thickness on the mask layer pattern, the second sacrificial layer pattern, the second etch stop layer pattern, the first sacrificial layer pattern and the first etch stop layer;
removing the mask layer pattern;
depositing a conductive material on the seed layer to form the body; and
planarizing the first etch stop layer, the seed layer and the first sacrificial layer pattern until the body is exposed.

16. The method of claim 7, wherein forming the body structure comprises:
subsequently forming a first etch stop layer, a first sacrificial layer, a second etch stop layer, a second sacrificial layer and a first mask layer pattern;
performing an etching process on the second sacrificial layer by using the first mask layer pattern as an etching mask to form a second sacrificial layer pattern having a horizontally extending first hole;
forming a second mask layer pattern having a second hole partially exposing the second etch stop layer on the first mask layer pattern, the second sacrificial layer pattern and the second etch stop layer;
etching the second etch stop layer and the first sacrificial layer by using the second mask layer pattern as an etch mask until the first etch stop layer is exposed to form a second etch stop layer pattern and a first sacrificial layer pattern;
removing the second mask layer pattern;
forming a seed layer having an uniform thickness on the first mask layer pattern, the second sacrificial layer pattern, the second etch stop layer pattern, the first sacrificial layer pattern and the first etch stop layer;
removing the first mask layer pattern;
depositing a conductive material on the seed layer to form the body; and
planarizing the first etch stop layer, the seed layer and the first sacrificial layer pattern until the body is exposed.

17. The method of claim 7, wherein forming the body structure comprises:
subsequently forming an etch stop layer and a sacrificial layer;
anisotropically etching the sacrificial layer to form a recess;
forming a mask layer pattern having a horizontally extending hole communicated with the recess on the sacrificial layer;
anisotropically etching a portion of the sacrificial layer exposed through the hole until the etch stop layer is exposed;
removing the mask layer pattern;
forming a seed layer having a relatively uniform thickness on the sacrificial layer and the etch stop layer;
depositing a conductive material on the seed layer to form the body; and
etching the etch stop layer, the seed layer and the sacrificial layer until the body is exposed.

18. The method of claim 7, wherein forming the body structure comprising:
subsequently forming a seed layer and a separation layer on a sacrificial layer;
forming a first photoresist layer pattern having a first hole on the separation layer;
forming a second photoresist layer pattern having a second hole having a width substantially larger than that of the first opening on the first photoresist layer pattern, the second hole being communicated with the first hole;
depositing a conductive material inside the first and second holes to form the body; and
removing the separation layer to separate the seed layer and the sacrificial layer from the body and the first photoresist pattern.

19. The method of claim 8, wherein forming the tip structure comprises:
anisotropically etching a first surface region of a substrate to form a first recess;
exposing a second surface region of the substrate enclosing the first surface are where the first recess is formed, the second surface region having an area substantially larger than that of the first surface region;
isotropically etching the second surface region to transform the first recess into a second recess;
anisotropically etching the second surface region where the second recess is formed to transform the second recess into a third recess;
forming a seed layer having a uniform thickness on the sacrificial layer such that the seed layer is conformed to an inner face of the third recess; and
forming the tip on the seed layer.

20. The method of claim 8, wherein forming the tip structure comprises:
anisotropically etching a first surface region of a substrate to form a first recess;
exposing a second surface region of the substrate enclosing the first surface region where the first recess is formed, the second surface region having an area substantially larger than that of the first surface region;
anisotropically etching the second surface region to transform the first recess into a second recess;
exposing a third surface region of the substrate enclosing the second surface region where the second recess is formed, the third surface region having an area substantially larger than that of the second surface region;
anisotropically etching the third surface region to transform the second recess into a third recess;
forming a seed layer on the sacrificial layer such that the seed layer is conformed to an inner face of the third recess; and
forming the tip on the seed layer.

21. The method of claim 8, wherein forming the tip structure comprises:
anisotropically etching a first surface region of a substrate to form a first recess;
exposing a second surface region of the substrate enclosing the first surface region where the first recess is formed, the second surface region having an area larger than that of the first surface region;
isotropically etching the second surface region to transform the first recess into a second recess;
forming a seed layer having a relatively uniform thickness on the substrate such that the seed layer is conformed to an inner face of the second recess; and
forming the tip on the seed layer.

22. The method of claim 8, wherein forming the tip structure comprises:
isotropically etching a first surface region of a substrate to form a recess;
forming a mask layer pattern having a hole exposing a second surface region of the substrate enclosing the first surface region where the recess is formed, the second surface region having an area substantially larger than that of the first region;
forming a seed layer on the substrate and the mask layer pattern such that the seed layer is conformed to inner faces of the hole and the recess;
removing the mask layer pattern; and
depositing a conductive material on the seed layer to form the tip.

23. The method of claim 8, further comprising partially removing a lower surface of the tip structure such that the tip is partially protruded.

24. The method of claim 7, wherein forming the tip structure comprises:
forming a first photoresist layer pattern having a first opening exposing the beam on the body structure, the first opening having a first width;
forming a first conductive member in the first opening of the first photoresist layer pattern;
forming a second photoresist layer pattern having a second opening exposing the first conductive member on the first photoresist layer pattern and the first conductive member, the second opening having a second width smaller than the first width; and
forming a second conductive member filling up the second opening.

25. The method of claim 7, wherein the first connecting member is formed by a screen printing method.
